(19) United States
(12) Patent Application Publication
(10) Pub. No.: US 2026/0068597 A1
(43) Pub. Date: Mar. 5, 2026

(54) APPARATUS FOR MANUFACTURING DISPLAY DEVICE AND METHOD OF MANUFACTURING THE DISPLAY DEVICE USING THE SAME

(71) Applicant: Samsung Display Co., LTD., Yongin-si (KR)

(72) Inventor: YONGGU KIM, Yongin-si (KR)

(21) Appl. No.: 19/189,544

(22) Filed: Apr. 25, 2025

(30) Foreign Application Priority Data
Aug. 28, 2024 (KR) 10-2024-0115473

(51) Int. Cl. H01L 21/687; H01L 21/66; H01L 21/68

(52) U.S. Cl. CPC H01L 21/68728

(57) ABSTRACT

An apparatus for manufacturing a display device includes a jig including a bottom portion on which a circuit portion of a circuit board is seated, a plurality of electromagnets disposed on the bottom portion to be spaced apart from each other, where plurality of electromagnets is male and female coupled to a plurality of protrusions of the circuit board protruding from the circuit portion, and a power supply which supplies current to the plurality of electromagnets.

This application claims priority to Korean Patent Application No. 10-2024-0115473, filed on Aug. 28, 2024, and all the benefits accruing therefrom under 35 U.S.C. § 119, the content of which in its entirety is herein incorporated by reference.

### BACKGROUND

### 1. Field

The disclosure relates to an apparatus for manufacturing a display device for fastening a connector and a method of manufacturing the display device using the apparatus. More specifically, the disclosure relates to an apparatus for manufacturing the display device for fastening the connector and the method for manufacturing the display device using the apparatus.

### 2. Description of the Related Art

As information technology develops, the importance of display devices, which are a primary communication media between users and information, is being heightened. Accordingly, various types of display device, such as liquid crystal display devices, organic light emitting display devices, plasma display devices, and the like, are widely used in various fields.

A display device typically includes a display area where a plurality of pixels is located, and a peripheral area where a driving circuit chip for driving the plurality of pixels is located.

In such a display device, connector may be located in peripheral area. A printed circuit board (“PCB”), which is one of the driving parts of the display device, may be located in the connector. For example, the circuit board may be a flexible printed circuit board (“FPCB”).

### SUMMARY

The disclosure provides an apparatus for a manufacturing a display device that ensure constant quality in a cable fastening operation.

The disclosure provides a method of manufacturing the display device using the apparatus for manufacturing the display device.

An embodiment of an apparatus for manufacturing a display device includes: a jig including a bottom portion on which a circuit portion of a circuit board is seated, a plurality of electromagnets disposed on the bottom portion to be spaced apart from each other, where the plurality of electromagnets is male and female coupled to a plurality of protrusions of the circuit board protruding from the circuit portion, and a power supply which supplies current to the plurality of electromagnets.

In an embodiment, first alignment marks may be defined on each of the plurality of protrusions, and second alignment marks may be defined on each of the plurality of electromagnets.

In an embodiment, each of the first and second alignment marks may have a cross shape in a plan view.

In an embodiment, the apparatus may further include a first sensor which detects the first alignment marks and the second alignment marks.

In an embodiment, the first sensor may include a vision camera.

In an embodiment, the apparatus may further include a plurality of second sensors disposed between the plurality of electromagnets, where the plurality of second sensors detects contacts between the plurality of electromagnets and the plurality of protrusions.

In an embodiment, the plurality of second sensors may include at least one selected from a current measurement sensor, a magnetic measurement sensor, and a touch sensor.

In an embodiment, the circuit board may be an inspection circuit board which is inserted into and fastened to a display panel of the display device on a stage to inspect the display panel, and the apparatus may further include a rail disposed the stage between the display panel and the circuit board on the jig to guide the jig on the stage to the display panel. In an embodiment, the plurality of protrusions may include a conductive material or a permanent magnet.

In an embodiment, the bottom portion may include an insulating material.

An embodiment of a method of manufacturing a display device includes preparing a circuit board including a plurality of protrusions, seating the circuit board on a jig including a bottom portion and a plurality of electromagnets disposed on the bottom portion to be spaced apart from each other, and determining whether the circuit board is seated in an exact position.

In an embodiment, the determining whether the circuit board is seated in the exact position may include detecting second alignment marks defined on each of the plurality of electromagnets and first alignment marks defined on each of the plurality of protrusions, and determining a degree of tilt of the circuit board based on the first alignment marks and the second alignment mark.

In an embodiment, when it is detected that the first alignment marks and the second alignment marks is not located in a same straight line, it may be determined that the circuit board is tilted and the circuit board is not seated in the exact position.

In an embodiment, the determining whether the circuit board is seated in the exact position may include detecting a non-contact portion where the plurality of electromagnets and the plurality of protrusions are not in contact with each other.

In an embodiment, the method may further include supplying current to the plurality of electromagnets, before the detecting the non-contact portion.

In an embodiment, the method may further include detecting a number of the non-contact portion and calculating a compensation distance of the circuit board based on the number of the non-contact portion.

In an embodiment, the method may further include turning off power supplied to the plurality of electromagnets when it is determined that the circuit board is not seated in the exact position.

In an embodiment, the method may further include performing the seating the circuit board on the jig again after the turning off the power when it is determined that the circuit board is not seated in the exact position.

In an embodiment, the method may further include coupling the circuit board to a display panel of the display device when it is determined that the circuit board is seated in the exact position.

In an embodiment, the method may further include moving the jig on a rail to move the circuit board toward the display panel, before the coupling the circuit board to the display panel.

An apparatus for manufacturing a display device according to an embodiment of the disclosure includes a jig including a bottom portion on which a circuit portion of a circuit board is seated, a plurality of electromagnets disposed on the bottom portion to be spaced apart from each other, where the plurality of electromagnets is male and female coupled to a plurality of protrusions protruding from the circuit portion of the circuit board, and a power supply which supplies current to the plurality of electromagnets. Accordingly, an operation of fastening the circuit board for inspecting the display device to the cable of the display device is performed consistently, such that a cable connection error may be minimized and constant quality of the cable connection operation may be secured.

### BRIEF DESCRIPTION OF THE DRAWINGS

The above and other features of embodiments of the disclosure will become more apparent by describing in further detail embodiments thereof with reference to the accompanying drawings, in which:

FIGS. 1 and 2 are views illustrating an apparatus for manufacturing a display device according to an embodiment.

FIG. 3 is a view illustrating a display panel coupled to a circuit board using the apparatus for manufacturing the display device of FIGS. 1 and 2.

FIG. 4 is a view illustrating a circuit board connected to the display panel of FIG. 3 using the apparatus for manufacturing the display device of FIGS. 1 and 2.

FIG. 5 is a view illustrating a jig on which the circuit board of FIG. 4 is seated.

FIGS. 6, 7, and 8 are views illustrating an operation of the apparatus for manufacturing the display device of FIGS. 1 and 2.

FIGS. 9, 10, 11, 12, 13, 14, 15, 16, 17, 18, 19, 20, 21, and 22 are views illustrating a method of manufacturing the display device using the apparatus for manufacturing the display device of FIGS. 1 and 2.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings. The same reference numerals are used for the same components in the drawings, and any repetitive detailed descriptions of the same components will be omitted or simplified.

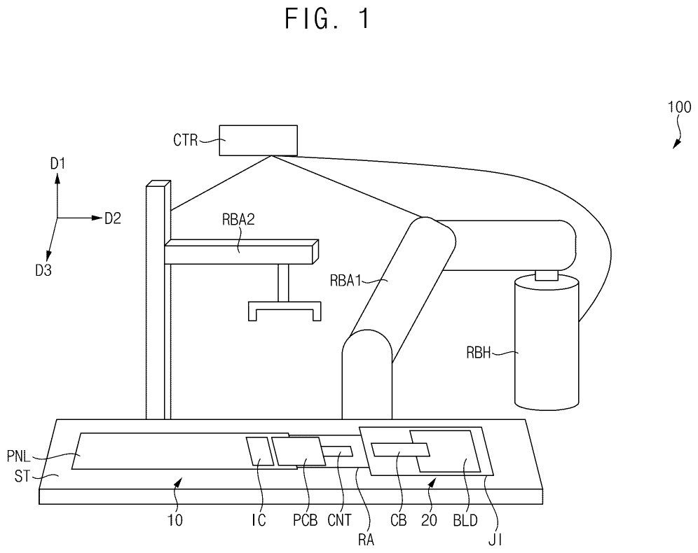

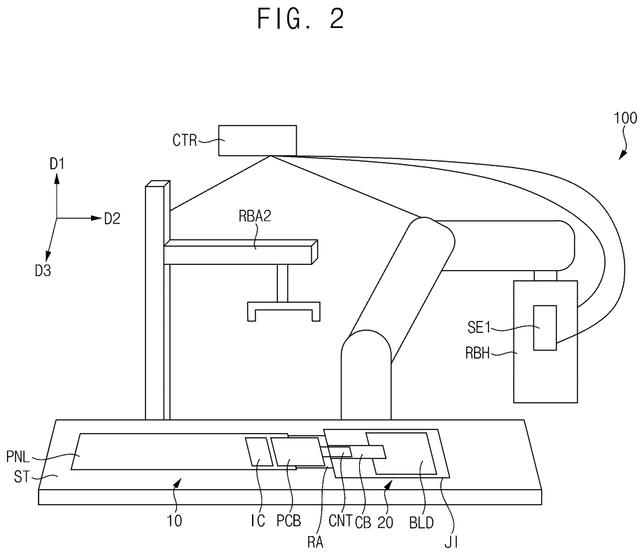

FIGS. 1 and 2 are views illustrating an apparatus for manufacturing a display device according to an embodiment.

Referring to FIGS. 1 and 2, an apparatus for manufacturing the display device 100 according to an embodiment of the disclosure may fasten an inspection circuit board 20 to a display device 10.

In an embodiment, the inspection circuit board 20 may be inserted into and fastened to the display device 10 to inspect the display device 10. In an embodiment, for example, the inspection circuit board 20 may perform aging inspection, lighting inspection, or the like, of the display device 10. Accordingly, the inspection circuit board 20 may check whether the display device 10 operates normally.

In an embodiment, the apparatus for manufacturing the display device 100 may include a first robot arm RBA1, a robot hand RBH, a first sensor SE1, a second robot arm RBA2, a controller CTR, a stage ST, a jig JI, and a rail RA.

In an embodiment, for example, the first robot arm RBA1 may be an articulated robot. Accordingly, the robot hand RBH may be moved in various directions by the first robot arm RBA1. However, the disclosure is not limited thereto.

In an embodiment, for example, the robot hand RBH may be connected to the first robot arm RBA1. The robot hand RBH may move by the first robot arm RBA1.

In an embodiment, the apparatus for manufacturing the display device 100 may include the first sensor SE1. In an embodiment, for example, the first sensor SE1 may be located on the robot hand RBH.

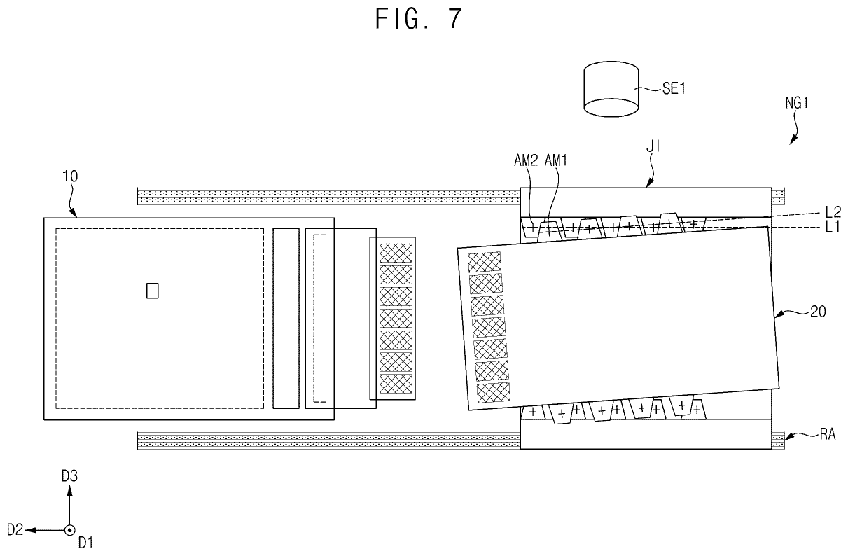

In an embodiment, the first sensor SE1 may include a vision camera. In an embodiment, the first sensor SE1 may detect first alignment marks and second alignment marks (e.g., first alignment marks AM1 and second alignment marks AM2 of FIG. 7), which will be described below. Accordingly, the first sensor SE1 may confirm whether the inspection circuit board 20 is seated in an exact position. Detailed features of the first sensor SE1 will be described below with reference to FIG. 7 et seq.

In an embodiment, for example, the second robot arm RBA2 may be controlled independently from the first robot arm RBA1. In an embodiment, for example, the second robot arm RBH2 may be an orthogonal robot. That is, the second robot arm RBA2 may only move in a first direction D1 and in an opposite direction to the first direction D1. However, the disclosure is not limited thereto.

In an embodiment, for example, the second robot arm RBA2 may fix the circuit board PCB for the panel. Accordingly, movement of the display device 10 may be effectively prevented.

In an embodiment, for example, the controller CTR may be connected to the first robot arm RBA1, the second robot arm RBA2, and the robot hand RBH. The controller CTR may control the movements of the first robot arm RBA1 and the second robot arm RBA2. In an embodiment, for example, the controller CTR may move or operate the robot hand RBH through the first robot arm RBA1 and effectively prevent the display device 10 from moving through the second robot arm RBA2.

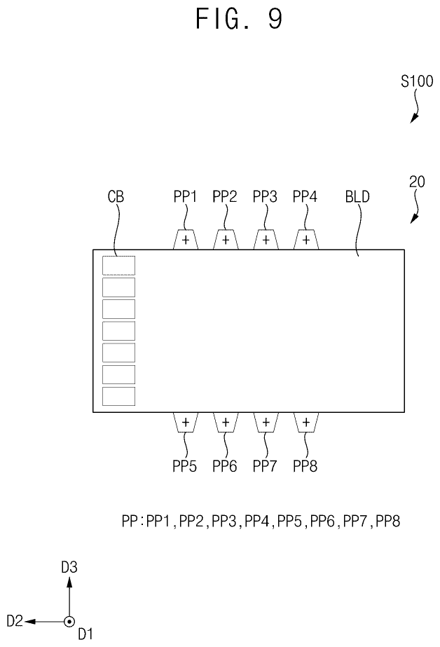

In an embodiment, the controller CTR may be connected to the first sensor SE1. The controller CTR may receive an image from the first sensor SE1. Accordingly, the controller CTR may determine whether the inspection circuit board 20 is seated in the exact position or predetermined desired position. A detailed description of the controller CTR will be provided below with reference to FIG. 9 et seq.

In an embodiment, the display device 10 may be located on the stage ST. In an embodiment, for example, the stage ST may be on a plane defined by a second direction D2 and a third direction D3. Here, each of the second direction D2 and the third direction D3 may cross the first direction D1. That is, the first direction D1, the second direction D2, and the third direction D3 may cross each other.

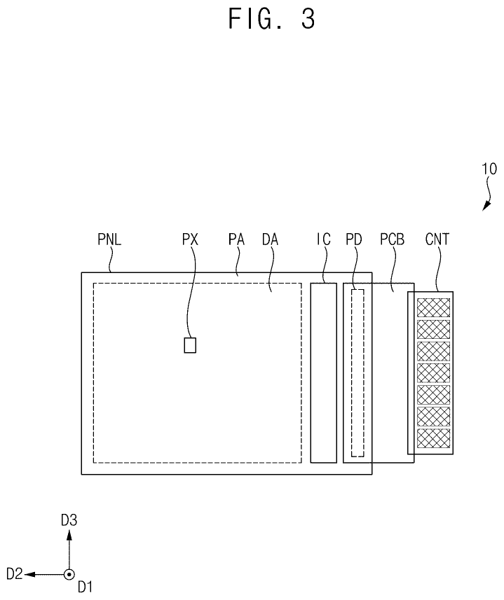

The display device 10 may include a display panel PNL, a driving integrated circuit IC, a circuit board PCB for the panel, and a connector CNT. The inspection circuit board 20 may include a cable CB and a board BLD. The cable CB included in the board BLD may be inserted and fastened to the connector CNT included in the display device 10. Detailed features of the display device 10 will be described below with reference to FIG. 3.

In an embodiment, for example, the display device 10 may be fixed to the stage ST, and the inspection circuit board 20 may move toward the display device 10 in a predetermined direction (e.g., the second direction D2 and/or an opposite direction to the second direction D2).

In a case where the inspection circuit board 20 does not make stable contact with the display device 10, the inspection may not be performed normally due to poor contact. Additionally, if a positional error occurs in the inspection circuit board 20, the display device 10 may be damaged while the inspection circuit board 20 is inserted into the display device 10.

Accordingly, the apparatus for manufacturing the display device 100 according to an embodiment of the disclosure may include a jig JI and a rail RA to ensure reliability of the fastening operation of the inspection circuit board 20 and the display device 10.

In an embodiment, the rail RA may be disposed between the display panel PNL and the inspection circuit board 20. In an embodiment, the inspection circuit board 20 may be seated on the jig JI. In an embodiment, the inspection circuit board 20 may be guided to the display panel PNL through the jig JI on the rail RA.

As the inspection circuit board 20 slides along the rail RA and is inserted and fastened to the display panel PNL, the fastening operation is performed consistently, fastening error may be minimized, and a certain quality of the fastening operation may be secured.

However, the disclosure is not limited thereto. In an embodiment, for example, the apparatus for manufacturing the display device 100 of FIGS. 1 and 2 may include more components, or the components may be omitted or replaced.

In an embodiment, the apparatus for manufacturing the display device 100 may include a displacement sensor (not shown). In an embodiment, for example, the displacement sensor may be located adjacent to the display device 10. Accordingly, the distance between the display device 10 and the inspection circuit board 20 may be measured.

The displacement sensor may provide a sensing value that serves as a basis for a control signal (e.g., generating a warning alarm, stopping operation, or the like) in case that the distance between the display device 10 and the inspection circuit board 20 is greater than a set value. Accordingly, movement of the jig JI in the direction (for example, the second direction D2 or the opposite direction to the second direction D2) may be stopped, and insertion or over-insertion of the cable CB may be effectively prevented. However, the disclosure is not limited thereto.

FIG. 3 is a view illustrating a display panel coupled to a circuit board using the apparatus for manufacturing the display device of FIGS. 1 and 2.

Referring to FIG. 3, an embodiment of the display panel PNL may include a display area DA and a peripheral area PA surrounding the display area DA in a plan view or when viewed in a thickness direction of the display panel PNL.

A plurality of pixels PX may be located in the display area DA. Each of the plurality of pixels PX may emit a predetermined color light. In an embodiment, for example, each of the plurality of pixels PX may emit red light, green light, blue light, or the like. The display panel PNL may provide an image by combining the color lights emitted from the plurality of pixels PX.

In an embodiment, the plurality of pixels PX might not be located in the peripheral area PA. The peripheral area PA may completely or partially surround the display area DA. However, the disclosure is not limited thereto. In another embodiment, for example, the plurality of pixels PX may also be located in the peripheral area PA.

The driving integrated circuit IC may be disposed in the peripheral area PA. In an embodiment, for example, the driving integrated circuit IC may be connected to the display panel PNL in various ways, such as chip on glass (“COG”), chip on film (“COF”), and chip on plastic (“COP”). The driving integrated circuit IC may generate electrical signals in response to power and signal received from an outside or an external device or circuitry. The power and the signal may be provided to the plurality of pixels PX.

A pad portion PD may be disposed in the peripheral area PA. The pad portion PD may be electrically connected to the driving integrated circuit IC through a wiring or conductive layer. The panel circuit board PCB may be disposed on the pad portion PD. The panel circuit board PCB may be electrically connected to the driving integrated circuit IC through the pad portion PD. In an embodiment, for example, the panel circuit board PCB may be attached to the pad portion PD using an adhesive member. However, the disclosure is not limited thereto.

The connector CNT may be disposed on one side of the panel circuit board PCB. The panel circuit board PCB may be electrically connected to the inspection circuit board 20 through the connector CNT. The panel circuit board PCB may be connected to the inspection circuit board 20. The panel circuit board PCB may transmit received control signals and/or power to the driving integrated circuit IC and the display panel PNL. Through this, the inspection circuit board 20 may inspect the panel circuit board PCB.

In an embodiment, for example, the panel circuit board PCB may be a flexible printed circuit board (“FPCB”) with flexible characteristics. The flexible printed circuit board may be folded, bent, or folded under the back of the display panel PNL and overlap at least a partial area of the display panel PNL.

However, the disclosure is not limited thereto. In an embodiment, for example, the display device 10 of FIG. 3 may include more components, or the components may be omitted or replaced.

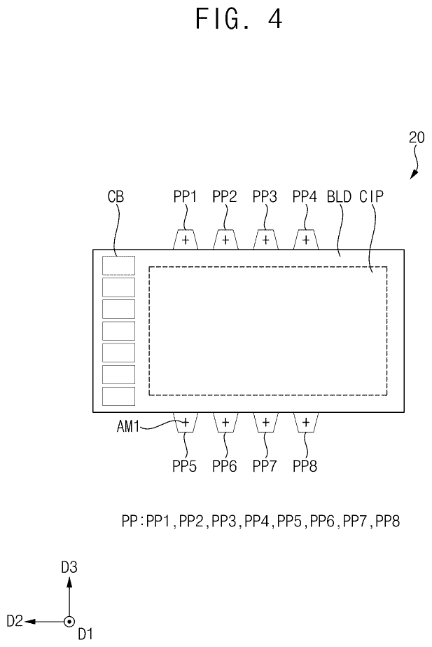

FIG. 4 is a view illustrating a circuit board connected to the display panel of FIG. 3 using the apparatus for manufacturing the display device of FIGS. 1 and 2.

Referring to FIGS. 2 and 4, in an embodiment, the inspection circuit board 20 may include the board BLD, the cable CB, and a plurality of protrusions PP.

In an embodiment, for example, the board BLD may be a driving power board that supplies driving current for inspection of the display device 10. In another embodiment, for example, the board BLD may be a pattern generator that outputs image signals for each pattern for inspection of the display device 10. In an embodiment, for example, a circuit portion CIP in which a plurality of lines is formed may be defined on the board BLD.

In an embodiment, for example, the cable CB included in the inspection circuit board 20 may be a flexible printed circuit board. The cable CB may be inserted and fastened to the connector CNT. As the cable CB connects the board BLD to the display device 10, the inspection process of the display device 10 may proceed.

In an embodiment, the plurality of protrusions PP may be formed to protrude from the circuit portion CIP of the inspection circuit board 20. In an embodiment, for example, the plurality of protrusions PP may be formed to protrude from the circuit portion CIP of the inspection circuit board 20 in the third direction D3 and in an opposite direction to the third direction D3.

In an embodiment, for example, the plurality of protrusions PP may be spaced apart from the circuit portion CIP and may protrude from a side parallel to a crossing direction in which the cable CB moves toward the display panel PNL in a plan view. In an embodiment, for example, the plurality of protrusions PP may be formed to protrude from a side extending parallel to the second direction D2.

In an embodiment, the plurality of protrusions PP may be spaced apart from each other. In an embodiment, for example, the plurality of protrusions PP may include a first protrusion PP1, a second protrusion PP2, a third protrusion PP3, a fourth protrusion PP4, a fifth protrusion PP5, a sixth protrusion PP6, a seventh protrusion PP7, and an eighth protrusion PP8.

In an embodiment, for example, the first protrusion PP1, the second protrusion PP2, the third protrusion PP3, and the fourth protrusion PP4 may be located in the third direction D3 from the circuit portion CIP. The fifth protrusion PP5, the sixth protrusion PP6, the seventh protrusion PP7, and the eighth protrusion PP8 may be located in the opposite direction to the third direction D3 from the circuit portion CIP.

In an embodiment, for example, the first protrusion PP1, the second protrusion PP2, the third protrusion PP3, and the fourth protrusion PP4 may be located to be spaced apart from each other in the second direction D2. The fifth protrusion PP5, the sixth protrusion PP6, the seventh protrusion PP7, and the eighth protrusion PP8 may be located to be spaced apart from each other in the second direction D2.

In an embodiment, the plurality of protrusions PP may include a conductive material or a permanent magnet. In an embodiment, for example, the inspection circuit board 20 may include plastic. In an embodiment, grooves may be defined or formed in the inspection circuit board 20 and the plurality of protrusions PP may be fitted or inserted into the grooves. However, the disclosure is not limited thereto. In an embodiment, for example, the plurality of protrusions PP may be coupled to the inspection circuit board 20 in various ways. In an embodiment, for example, the plurality of protrusions PP may be coupled to the inspection circuit board 20 using an adhesive member.

In an embodiment, for example, where the plurality of protrusions PP include the permanent magnet, a polarity of the permanent magnet may be opposite to the polarity of the plurality of electromagnets EM, which will be described below.

In an embodiment, the first alignment marks AM1 may be provided on each of the plurality of protrusions PP. In such an embodiment, it can be determined whether the inspection circuit board 20 is located in the exact position through the first alignment marks AM1.

In an embodiment, the first alignment marks AM1 may have a cross shape in a plan view. However, the disclosure is not limited thereto. In an embodiment, for example, the first alignment marks AM1 may be changed into various shapes representing north, south, east and west.

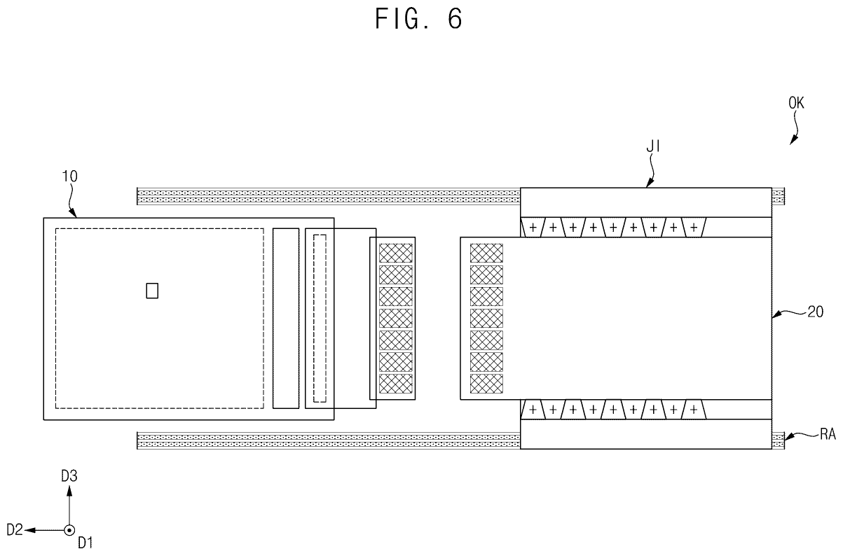

Detailed features of the first alignment marks AM1 will be described below with reference to FIGS. 6, 7, and 8.

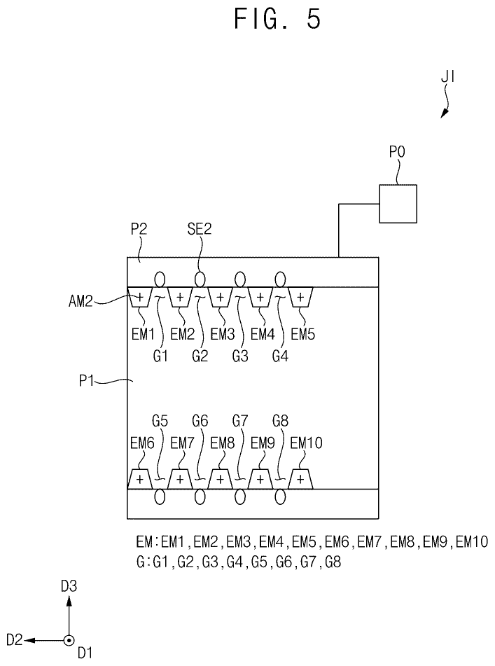

FIG. 5 is a view illustrating a jig on which the circuit board of FIG. 4 is seated.

Referring to FIGS. 2, 4, and 5, in an embodiment, the jig JI may include a bottom portion P1, a support portion P2, a plurality of electromagnets EM, and the plurality of second sensors SE2.

In an embodiment, the circuit portion CIP of the inspection circuit board 20 may be seated on the bottom portion P1. In an embodiment, the bottom portion P1 may include an insulating material to effectively prevent short circuit of the circuit portion CIP. In an embodiment, for example, the insulating material may include SUS, or the like. However, the disclosure is not limited thereto.

The support portion P2 may protrude from the bottom portion P1 in the first direction D1. In an embodiment, the plurality of electromagnets EM may be spaced apart from each other along an extension direction of the support part P2 (e.g., the second direction D2) on the bottom portion P1. In an embodiment, for example, the plurality of electromagnets EM may be attached to and detached from the support portion P2.

In an embodiment, the plurality of electromagnets EM may be spaced apart from each other. In an embodiment, for example, the plurality of electromagnets EM may include a first electromagnet EM1, a second electromagnet EM2, a third electromagnet EM3, a fourth electromagnet EM4, a fifth electromagnet EM5, a sixth electromagnet EM6, a seventh electromagnet EM7, an eighth electromagnet EM8, a ninth electromagnet EM9, and a tenth electromagnet EM10.

In an embodiment, for example, the first electromagnet EM1, the second electromagnet EM2, the third electromagnet EM3, the fourth electromagnet EM4, and the fifth electromagnet EM5 may be located in the third direction D3 from the bottom portion P1. The sixth electromagnet EM6, the seventh electromagnet EM7, the eighth electromagnet EM8, the ninth electromagnet EM9, and the tenth electromagnet EM10 may be located in the opposite direction to the third direction D3 from the bottom portion P1.

In an embodiment, for example, the first electromagnet EM1, the second electromagnet EM2, the third electromagnet EM3, the fourth electromagnet EM4, and the fifth electromagnet EM5 may be located spaced apart from each other in the second direction D2. The sixth electromagnet EM6, the seventh electromagnet EM7, the eighth electromagnet EM8, the ninth electromagnet EM9, and the tenth electromagnet EM10 may be located spaced apart from each other in the second direction D2.

In an embodiment, the plurality of electromagnets EM may receive current from a power supply PO. The plurality of electromagnets EM may generate magnetic force by receiving the current.

In an embodiment, for example, the plurality of electromagnets EM may include a material that may generate magnetic force by receiving the current. In an embodiment, for example, the plurality of electromagnets EM may include iron. However, the disclosure is not limited thereto.

In an embodiment, the plurality of electromagnets EM of the jig JI may be male and female coupled to the plurality of protrusions PP of the inspection circuit board 20. That is, the plurality of electromagnets EM of the jig JI may be coupled to the plurality of protrusions PP of the inspection circuit board 20 by an interlocking joint. In an embodiment, for example, the plurality of electromagnets EM may have a first parallelogram shape. The first parallelogram shape may be wide at a top and narrow at a bottom shape. The plurality of protrusions PP may also have a second parallelogram shape. The second parallelogram shape may be wide at a bottom and narrow at a top shape. Accordingly, the inspection circuit board 20 and the plurality of protrusions PP may be coupled to each other.

In an embodiment, the second alignment marks AM2 may be located on each of the plurality of electromagnets EM. In such an embodiment, it may be determined whether the inspection circuit board 20 is placed in the exact position through the second alignment marks AM2.

In an embodiment, the second alignment marks AM2 may have the cross shape in a plan view. However, the disclosure is not limited thereto. In an embodiment, for example, the second alignment marks AM2 may be changed into various shapes representing the north, south, east and west.

Detailed features of the second alignment marks AM2 will be described below with reference to FIGS. 6, 7, and 8.

In an embodiment, the plurality of second sensors SE2 may be disposed in target holes G defined between the plurality of electromagnets EM. The plurality of second sensors SE2 may detect contact between the plurality of electromagnets EM and the plurality of protrusions PP.

In an embodiment, for example, a first target hole G1 may be defined between the first electromagnet EM1 and the second electromagnet EM2, a second target hole G2 may be defined between the second electromagnet EM2 and the third electromagnet EM3, a third target hole G3 may be defined between the third electromagnet EM3 and the fourth electromagnet EM4, a fourth target hole G4 may be defined between the fourth electromagnet EM4 and the fifth electromagnet EM5, a fifth target hole G5 may be defined between the sixth electromagnet EM6 and the seventh electromagnet EM6, a sixth target hole G6 may be defined between the seventh electromagnet EM7 and the eighth electromagnet EM8, a seventh target hole G7 may be defined between the eighth electromagnet EM8 and the ninth electromagnet EM9, and an eighth target hole G8 may be defined between the ninth electromagnet EM9 and the tenth electromagnet EM10.

By locating the plurality of second sensors SE2 in each of the target holes G, a portion where the plurality of electromagnets EM and the plurality of protrusions PP are not in contact may be detected.

In an embodiment, the plurality of second sensors SE2 may include a current measurement sensor, a magnetic measurement sensor, or a touch sensor. These maybe used alone or in combination with each other.

In an embodiment, for example, the current measurement sensor may output current, measure whether the output electrode is energized, and detect contact between the plurality of electromagnets EM and the plurality of protrusions PP.

In an embodiment, for example, the magnetic measurement sensor may detect magnetic force generated from a permanent magnet, and in case that the magnetic force is greater than a threshold, the magnetic measurement sensor may detect contact between the plurality of electromagnets EM and the plurality of protrusions PP.

In an embodiment, for example, the touch sensor may be a capacitive sensor. The capacitance sensor may detect contact between the plurality of electromagnets EM and the plurality of protrusions PP by measuring a change in capacitance.

However, the disclosure is not limited thereto. In an embodiment, for example, the plurality of second sensors SE2 may include various sensors capable of detecting the contact of the plurality of electromagnets EM and the plurality of protrusions PP.

The embodiments shown in FIGS. 4 and 5 are merely illustrative, and the disclosure is not limited thereto. In an embodiment, for example, the number, shape, arrangement spacing, size, or the like, of the plurality of protrusions PP and the plurality of electromagnets EM may be changed in various ways.

In an embodiment, for example, as shown in FIGS. 4 and 5, the plurality of protrusions PP and the plurality of electromagnets EM are described as having the parallelogram shape, however the disclosure is not limited thereto. In an embodiment, for example, the plurality of protrusions PP and the plurality of electromagnets EM may be changed in various shapes to enable male and female coupled. In an embodiment, for example, where the plurality of protrusions PP are triangular, the plurality of electromagnets EM may be formed in a way such that the target hole between the plurality of electromagnets EM has the triangular shape in a plan view.

In an embodiment, as shown in FIGS. 4 and 5, the inspection circuit board 20 is fixed to the jig JI by the plurality of electromagnets EM, however the disclosure is not limited thereto.

In an embodiment, for example, the jig JI may further include a physical fixing device. In an embodiment, for example, the physical fixing device may fix the inspection circuit board 20 even if the current supply to the plurality of electromagnets EM is interrupted. In an embodiment, for example, the physical fixing device may include a lock that is manually removable, a hook that is automatically operated by a controller, or the like.

FIGS. 6, 7, and 8 are views illustrating an operation of the apparatus for manufacturing the display device of FIGS. 1 and 2.

Referring to FIG. 6, in case that it is determined that the inspection circuit board 20 is seated in the exact position on the jig JI, the inspection circuit board 20 may move along the rail RA toward the display device 10.

However, as shown in FIG. 7, the inspection circuit board 20 may be arranged to have a twist error NG1 on the jig JI.

The twist error NG1 may be detected by connecting the first alignment marks AM1 and the second alignment marks AM2. The first alignment marks AM1 and the second alignment marks AM2 may be detected using the first sensor SE1 (e.g., the vision camera).

In an embodiment, for example, a first virtual (or imaginary) line L1 connecting the first alignment marks AM1 and a second virtual (or imaginary) line L2 connecting the second alignment marks AM2 may not be parallel with each other. In this case, it may be determined that the twist error NG1 has occurred.

In case that the inspection circuit board 20 is inserted into the display device 10 with the twist error NG1, the display device 10 and/or the inspection circuit board 20 may be damaged.

In order to minimize or eliminate the twist error NG1, the apparatus of manufacturing the display device (the apparatus of manufacturing the display device 100 of FIG. 1) according to an embodiment of the disclosure may seat the inspection circuit board 20 on the jig JI, and determine whether the inspection circuit board 20 is located at the exact position (or predetermined position) on the jig JI. The error control may be repeated until it is determined that the inspection circuit board 20 is located at the exact position.

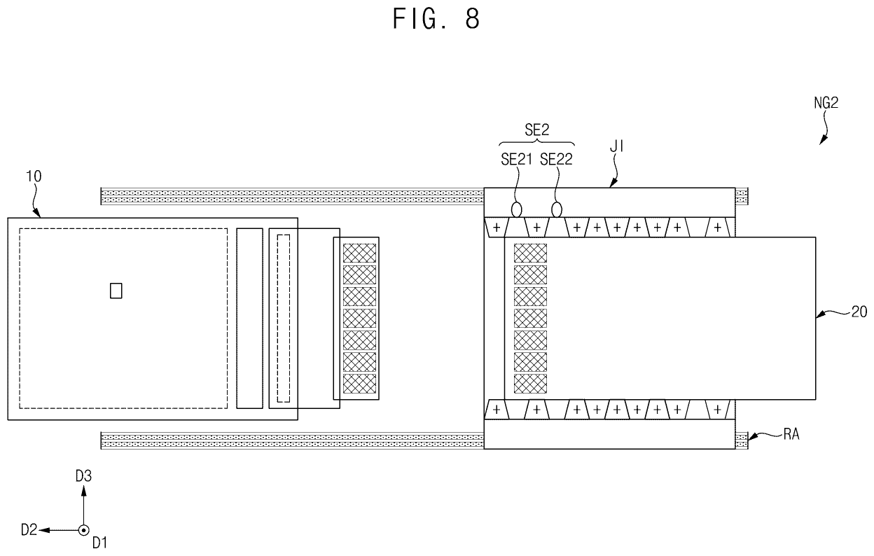

On the other hand, as shown in FIG. 8, the inspection circuit board 20 may be arranged to have a moving distance error NG2.

The moving distance error NG2 may be detected using the plurality of second sensors SE2.

As shown in FIG. 8, if the virtual lines (for example, the first virtual line L1 and the second virtual line L2) are parallel with each other, it may be determined that the twist error NG1 has not occurred. However, in case that the plurality of electromagnets EM and the plurality of protrusions PP do not contact the plurality of second sensors SE2 disposed in the target holes (e.g., the target holes G of FIG. 4), the plurality of second sensors SE2 may generate a certain signal (e.g., current, voltage, capacitance, or the like). In this case, it may be determined that the moving distance error NG2 has occurred.

In an embodiment, for example, the plurality of second sensors SE2 may include a first second sensor SE21, a second second sensor SE22, and remaining sensors. In a portion where the first second sensor SE21 and the second second sensor SE22 are disposed, the first second sensor SE21 and the second second sensor SE22 detect the non-contact of the inspection circuit board 20 with the jig JI, and the remaining sensors may detect the contact of the inspection circuit board 20 with the jig JI. In this case, it may be determined that the inspection circuit board 20 may be desired to be located on the jig JI at a position further moved in the second direction D2.

When the inspection circuit board 20 is inserted toward the display device 10 with the moving distance error NG2, the connector of the display device 10 (e.g., the connector CNT of FIG. 2) may be over-inserted or less-inserted (e.g., in the case of FIG. 8, the less-inserted may occur). As a result, the inspection process might not proceed due to the poor contact, or the display device 10 and/or the inspection circuit board 20 may be damaged.

In order to minimize or eliminate the moving distance error NG2, the apparatus of manufacturing the display device manufacturing apparatus (the apparatus for manufacturing the display device 100 of FIG. 1) according to an embodiment of the disclosure may seat the inspection circuit board 20 on the jig JI, and determine whether the inspection circuit board 20 is located at the exact position (or predetermined position) on the jig JI. The error control may be repeated until it is determined that the inspection circuit board 20 is located at the exact position.

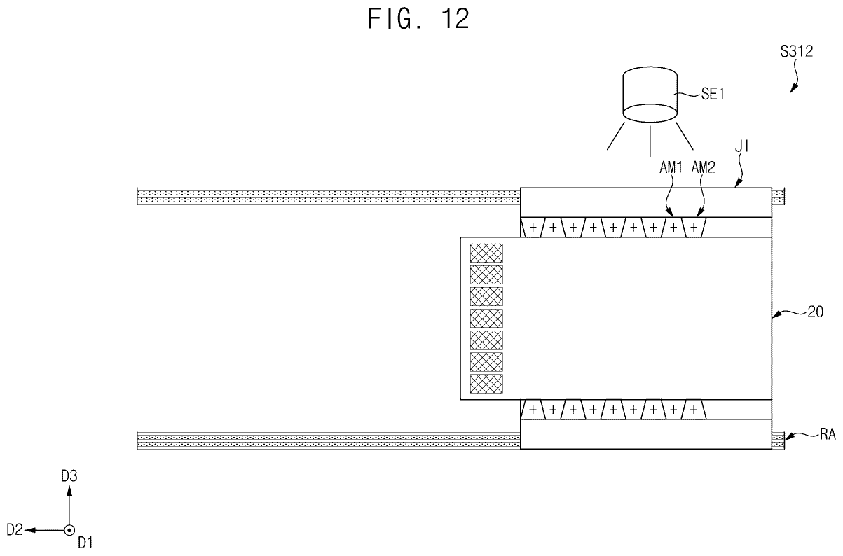

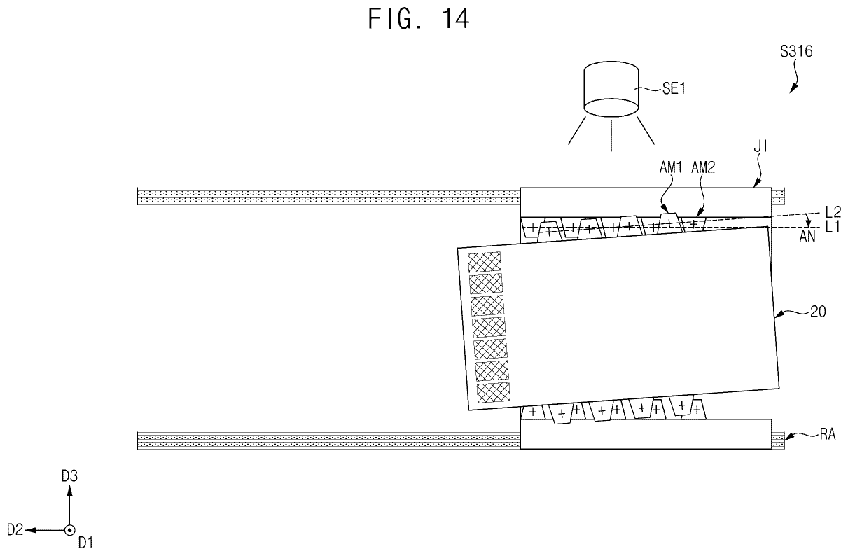

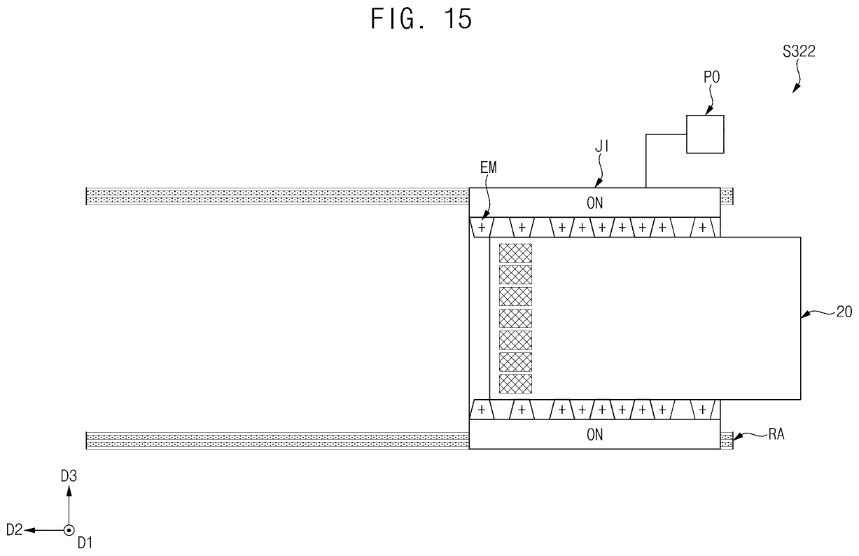

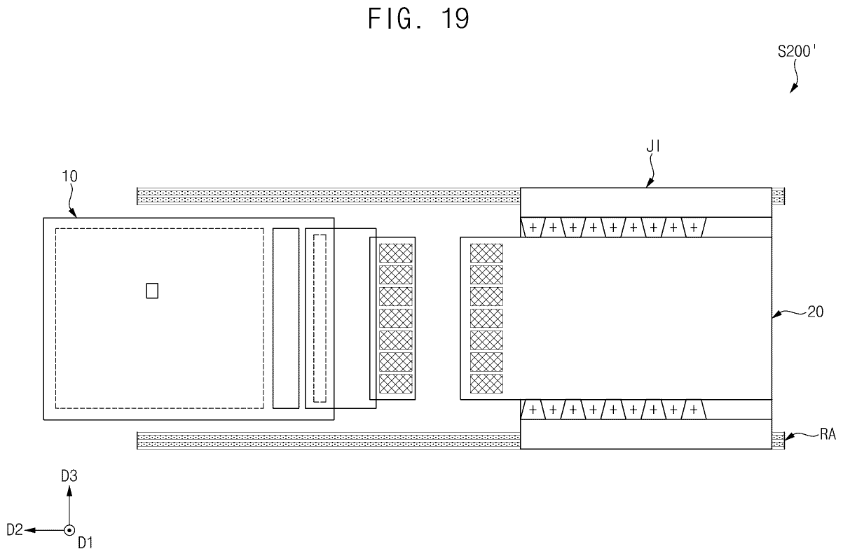

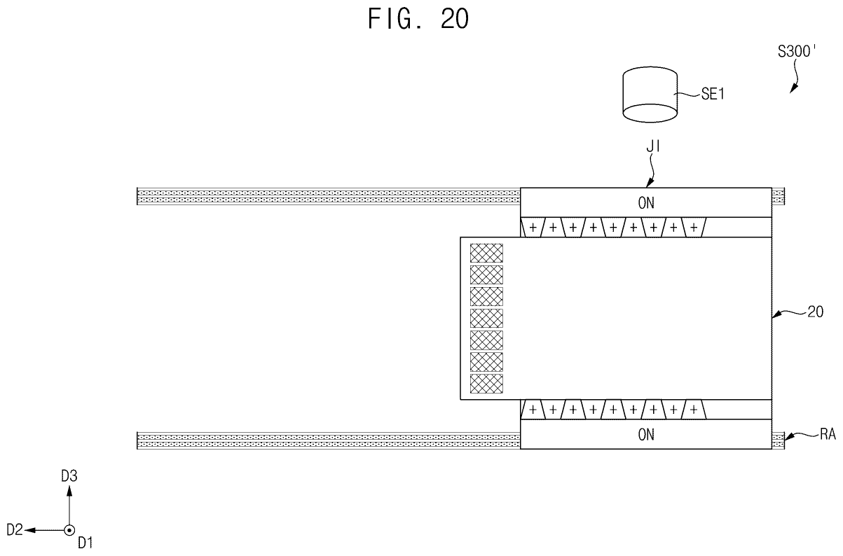

FIGS. 9, 10, 11, 12, 13, 14, 15, 16, 17, 18, 19, 20, 21, and 22 are views illustrating a method of manufacturing the display device using the apparatus for manufacturing the display device of FIGS. 1 and 2.

Hereinafter, for convenience of description, any repetitive detailed description of the same or like elements of the apparatus of manufacturing the display device as those described above with reference to FIGS. 1, 2, 3, 4, 5, 6, 7, and 8 will be omitted or simplified.

Referring to FIG. 9, in an embodiment, the method may include preparing a circuit board (e.g., an inspection circuit board) 20 for inspection including the plurality of protrusions PP (S100).

As described above, the apparatus of manufacturing the display device (e.g., the apparatus for manufacturing the display device 100 of FIGS. 1 and 2) according to an embodiment of the disclosure may fasten the inspection circuit board 20 to the display device 10. In an embodiment, the inspection circuit board 20 may be inserted into and fastened to the display device 10 to inspect the display device 10. Accordingly, whether the display device 10 operates normally may be checked.

In an embodiment, the rail RA may be disposed between the display panel (for example, the display panel PNL included in the display device 10 of FIG. 1) and the inspection circuit board 20. In an embodiment, the inspection circuit board 20 may be seated on the jig JI. In an embodiment, the inspection circuit board 20 may be guided to the display panel through the jig JI on the rail RA.

In an embodiment, the inspection circuit board 20 may include the board BLD, the cable CB, and the plurality of protrusions PP.

In an embodiment, for example, the circuit portion CIP in which the plurality of lines are formed on the board BLD may be defined.

The cable CB may be inserted and fastened to the connector CNT. As the cable CB connects the board BLD to the display device 10, the inspection process of the display device 10 may proceed.

In an embodiment, the plurality of protrusions PP may be formed to protrude from the circuit portion CIP of the circuit board 20.

In an embodiment, the plurality of protrusions PP may include a conductive material or a permanent magnet. In an embodiment, for example, the inspection circuit board 20 may include plastic. In an embodiment, grooves may be defined in the inspection circuit board 20, and the plurality of protrusions PP may be fitted or inserted into the grooves.

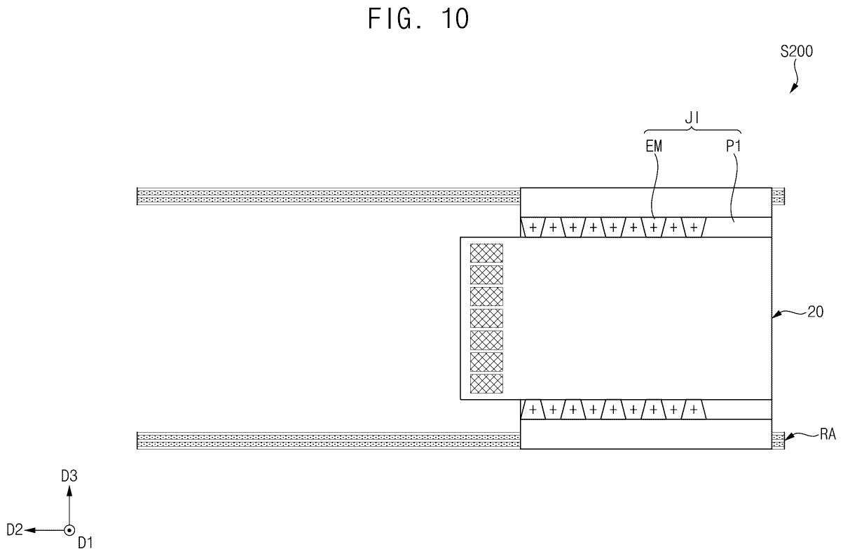

Referring to FIG. 10, in an embodiment, the method may include seating the circuit board 20 on the jig JI (S200). In an embodiment, the jig JI may include the bottom part P1, the support part P2, the plurality of electromagnets EM, and the plurality of second sensors SE2.

In an embodiment, the circuit portion of the inspection circuit board 20 may be seated on the bottom portion P1. In an embodiment, the bottom portion P1 may include an insulating material to effectively prevent the short circuit of the circuit portion CIP.

In an embodiment, the plurality of electromagnets EM may generate the magnetic force by receiving the current from the power supply. In an embodiment, for example, the plurality of electromagnets EM may include a material that may generate magnetic force by receiving the current. In an embodiment, for example, the plurality of electromagnets EM may include iron. However, the disclosure is not limited thereto.

In an embodiment, the plurality of electromagnets EM of the jig JI may be male and female coupled to the plurality of protrusions PP of the inspection circuit board 20.

In an embodiment, the jig JI may be located on the rail RA. In an embodiment, for example, in case that it is determined that the inspection circuit board 20 is seated in the exact position, the inspection circuit board 20 may move along the rail RA toward the display device 10.

Referring to FIGS. 4, 5, 11, 12, 13, and 14, in an embodiment, the determining whether the circuit board 20 is seated in the exact position (S300) may include, detecting the second alignment marks AM2 located on each of the plurality of electromagnets EM and the first alignment marks AM1 located on each of the plurality of protrusions PP (S312) and determining the degree of tilt of the inspection circuit board 20 by connecting the first alignment marks AM1 and the second alignment marks AM2 (S314).

In an embodiment, the first alignment marks AM1 may be located on each of the plurality of protrusions PP. The second alignment marks AM2 may be located on each of the plurality of electromagnets EM. The first alignment marks AM1 and the second alignment marks AM2 may have the cross shape. The first alignment marks AM1 and the second alignment marks AM2 may be detected using the first sensor SE1.

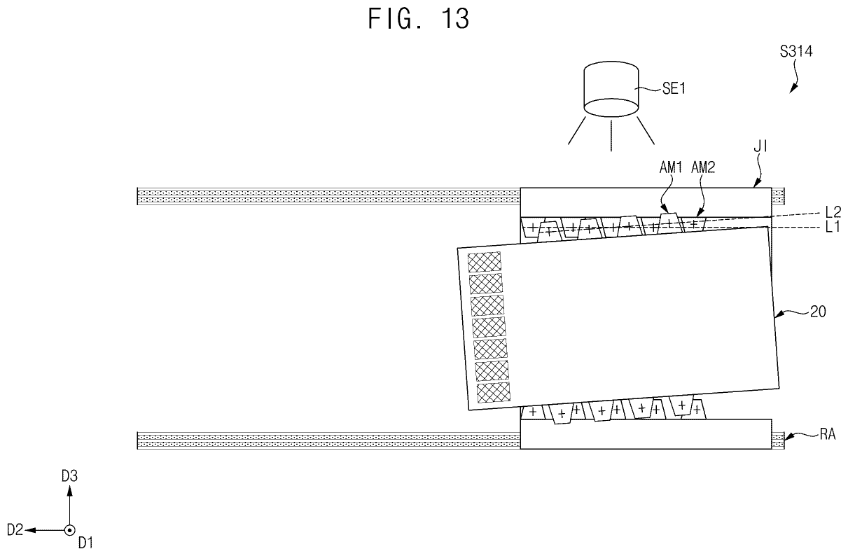

In an embodiment, for example, as shown in FIG. 13, the inspection circuit board 20 may be located on the jig JI to have a twist error (e.g., the twist error NG1 of FIG. 7).

In an embodiment, for example, the first virtual line L1 connecting the first alignment marks AM1 and the second virtual line L2 connecting the second alignment marks AM2 might not be parallel with each other. In this case, it may be determined that the twist error NG1 has occurred. In other words, in an embodiment, in case that the first alignment marks AM1 and the second alignment marks AM2 are not located on a same straight line, the inspection circuit board 20 may be determined to be tilted, and it may be determined that the inspection circuit board 20 is not seated in the exact position (S316).

In this case, the robot arm (e.g., the robot arm RBH of FIG. 1) lifts the inspection circuit board 20 again and rotates the inspection circuit board 20 by a certain angle AN, and the inspection circuit board 20 may be seated again on the jig JI.

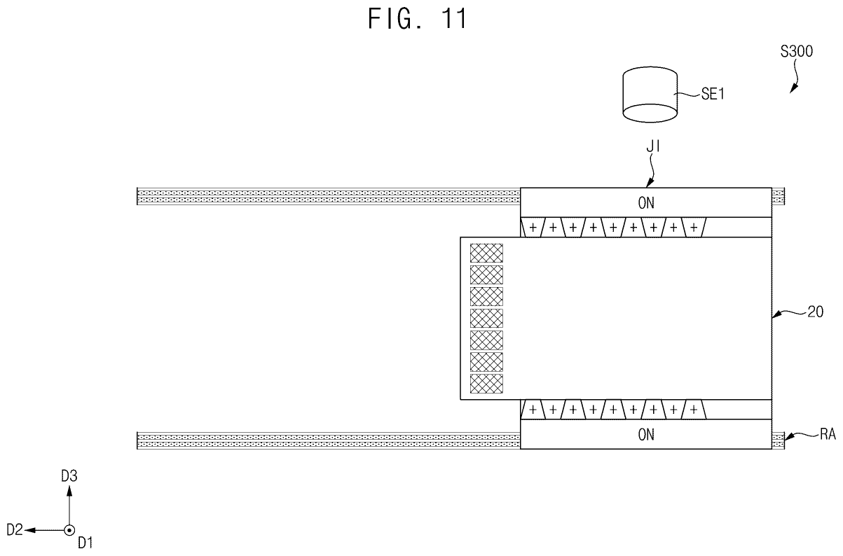

Referring to FIGS. 11, 15, 16, and 17, in an embodiment, the determining whether the inspection circuit board 20 is seated in the exact position may include supplying the current to the plurality of electromagnets EM (S322), and may include detecting a portion of the plurality of electromagnets EM not in contact with the protrusions PP (e.g., the plurality of protrusions of FIG. 4) (i.e., detecting the non-contact portion S324).

In an embodiment, the plurality of electromagnets EM may receive the current from the power supply PO. The plurality of electromagnets EM may generate the magnetic force by receiving the current.

In an embodiment, the plurality of second sensors SE2 may be disposed in the target holes G defined between the plurality of electromagnets EM. The plurality of second sensors SE2 may detect the contact of the plurality of electromagnets EM with the plurality of protrusions PP.

In an embodiment, for example, in case that the magnetic force is generated in the plurality of electromagnets EM, the contact between the plurality of electromagnets EM and the plurality of protrusions may be detected.

In an embodiment, the plurality of second sensors SE2 may be the current measurement sensor, the magnetic measurement sensor, and the touch sensor. These may be used alone or in combination with each other.

In an embodiment, the detecting the portion where the plurality of electromagnets EM and the plurality of protrusions are not in contact, if the current exceeding a reference current range is detected, it may be determined that the inspection circuit board 20 is not seated in the exact position (S326, S328).

However, the disclosure is not limited thereto.

In an embodiment, for example, in case that a button is located and the plurality of protrusions PP press the button, a signal may be transmitted to the controller to detect the contact between the electromagnets EM and the plurality of protrusions. In this case, the contact between the plurality of electromagnets EM and the plurality of protrusions may be detected without the magnetic force being generated.

In another embodiment, for example, the detecting the portion where the plurality of electromagnets EM and the plurality of protrusions are not in contact, if the magnetic force is greater than a threshold or a change in the capacitance is detected, it may be determined that the inspection circuit board 20 is not seated in the exact position.

In an embodiment, the method may include, in case that it is determined that the inspection circuit board 20 is not seated in the exact position, calculating the number of portions (i.e., the number of non-contact portions) where the plurality of electromagnets EM and the plurality of protrusions are not in contact (S326) and calculating a compensation distance CL for moving the inspection circuit board 20 based on the number of non-contact portions. The position error of the inspection circuit board 20 may be compensated for in step (S328).

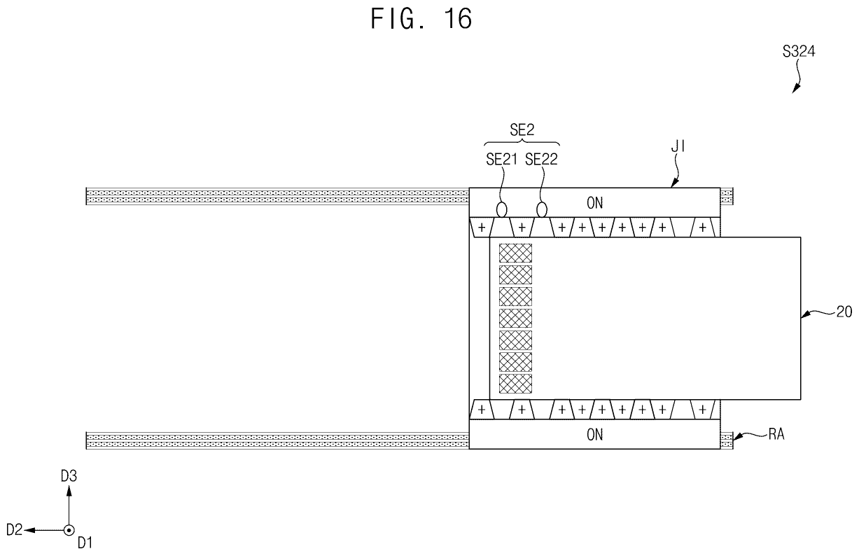

In an embodiment, for example, the first second sensor SE21 and the second second sensor SE22 may detect the non-contact portion between the jig JI and the inspection circuit board 20. In an embodiment, for example, in the case of FIG. 16, the number of non-contact portions may be four. For convenience of explanation, sensors located in the opposite direction to the third direction D3 of the inspection circuit board 20 may be omitted.

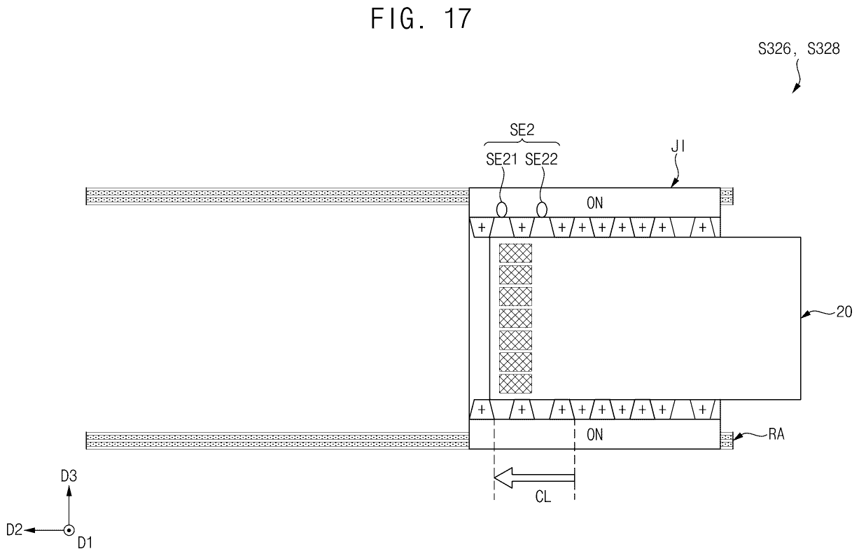

Based on the number of non-contact portions, the controller may determine that the inspection circuit board 20 should move by a certain compensation distance CL in the second direction D2. In an embodiment, for example, in the case of FIG. 17, since two target holes are empty in the second direction D2, the compensation distance CL may be a movement distance that fills the two empty target holes.

In this case, the robot arm (e.g., the robot arm RBH of FIG. 1) may lift the inspection circuit board 20 again and move it in the straight line by the compensation distance CL, and the inspection circuit board 20 may be seated again on the jig JI.

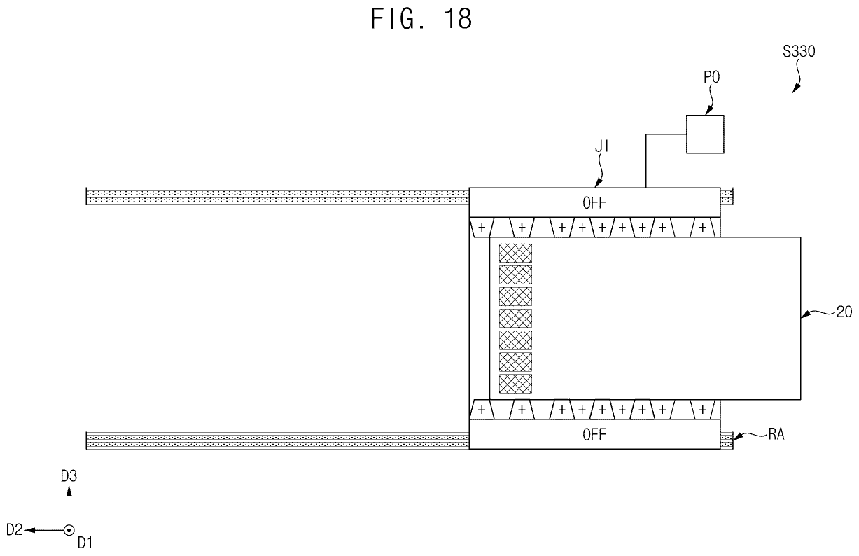

Referring to FIG. 18, the method may include the turning off the power supplied to the plurality of electromagnets in case that it is determined that the inspection circuit board 20 is not seated in the exact position (S330).

In an embodiment, for example, in a state in which the magnetic force is generated, the position error (e.g., the twist error NG1 of FIG. 7 and/or the moving distance error NG2 of FIG. 8) of the inspection circuit board 20 may be detected. In order to compensate for the position error, the magnetic force may be removed to lift the inspection circuit board 20 from the jig JI, and then the inspection circuit board 20 may be located on the jig JI again.

In an embodiment, for example, the magnetic force may be removed by turning off the power supplied to the plurality of electromagnets from the power supply PO.

However, the disclosure is not limited thereto. In an embodiment, for example, in case that the plurality of protrusions PP include the permanent magnet, the polarity of the magnetic force generated from the plurality of electromagnets EM may be controlled to have a same polarity as the polarity of the permanent magnet. Using a repulsive force between the plurality of protrusions PP and the plurality of electromagnets EM having the same polarities, the chucking of the inspection circuit board 20 may be released from the jig JI, and the inspection circuit board 20 may be located again in another position.

Referring to FIGS. 18, 19, and 20, if it is determined that the inspection circuit board 20 is not seated in the correct position, the method may be started again from the seating the inspection circuit board 20 on the jig JI after turning off the power. In an embodiment, the inspection circuit board 20 may be re-seated on the jig JI (S200′), and whether the inspection circuit board 20 is seated in the exact position may be determined (S300′).

The above processes may be repeated until it is determined that the inspection circuit board 20 is seated in the exact position.

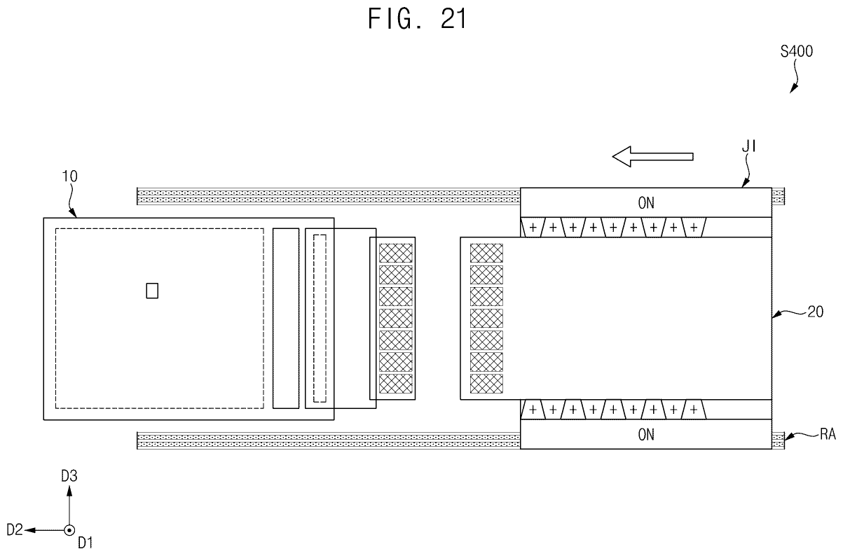

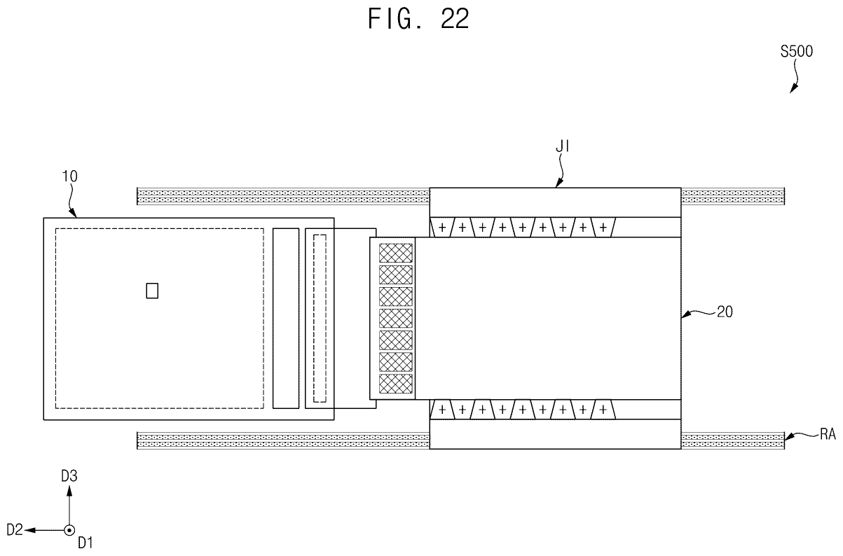

Referring to FIGS. 21 and 22, in case that the inspection circuit board 20 is seated in the correct position is determined, the inspection circuit board 20 may be moved toward the display device (e.g., the display device 10 including the display panel PNL of FIG. 1) by moving the jig JI on the rail RA (S400) and coupling the inspection circuit board 20 to the display panel (S500), may be performed.

The inspection circuit board 20 may be moved toward the display panel while being fixed by the plurality of electromagnets EM.

The jig JI may be moved on the rail RA in various ways, such as a magnetic levitation method or an LM guide method.

A stroke of the jig JI may be stored in the controller. The jig JI may move in the second direction D2 on the rail RA by the stroke.

In an embodiment, as described above, a laser sensor or the like may be located at the display device 10. The laser sensor may measure the distance between the display device 10 and the inspection circuit board 20 to effectively prevent over-inserted or less-inserted.

After the inspection circuit board 20 is coupled to the display panel, the lighting inspection, or the like, may be performed.

As described above, in case that using the apparatus of manufacturing the display device and the method of manufacturing the display device using the apparatus according to an embodiment of the disclosure, the cable (e.g., the cable CB of FIG. 1) fastening operation is performed consistently, the cable fastening error may be minimized, and constant quality for the cable fastening operation may be secured.

The apparatus of manufacturing the display device according to the embodiments may be applied to a manufacturing process of the display device included in a computer, a notebook, a mobile phone, a smartphone, a smart pad, a portable media player (PMP), a personal digital assistant (PDA), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
a jig including a bottom portion on which a circuit portion of a circuit board is seated, a plurality of electromagnets disposed on the bottom portion to be spaced apart from each other, wherein of the plurality of electromagnets is male and female coupled to a plurality of protrusions of the circuit board protruding from the circuit portion; and
a power supply which supplies current to the plurality of electromagnets.

2. The apparatus for claim 1, wherein
first alignment marks are defined on each of the plurality of protrusions, and
second alignment marks are defined on each of the plurality of electromagnets.

3. The apparatus for claim 1, wherein each of the first and second alignment marks has a cross shape in a plan view.

4. The apparatus for claim 1, further comprising:
a first sensor which detects the first alignment marks and the second alignment marks.

5. The apparatus for claim 4, wherein the first sensor comprises a vision camera.

6. The apparatus for claim 1, further comprising:
a plurality of second sensors disposed between the plurality of electromagnets, wherein the plurality of second sensors detects contacts between the plurality of electromagnets and the plurality of protrusions.

7. The apparatus for claim 6, wherein the plurality of second sensors includes at least one selected from a current measurement sensor, a magnetic measurement sensor, and a touch sensor.

8. The apparatus for claim 1,
wherein the circuit board is an inspection circuit board which is inserted into and fastened to a display panel of the display device on a stage to inspect the display panel, and
the apparatus further comprises: a rail disposed the stage between the display panel and the circuit board on the jig to guide the jig on the stage to the display panel.

9. The apparatus for claim 1, wherein the plurality of protrusions includes a conductive material or a permanent magnet.

10. The apparatus for claim 1, wherein the bottom portion includes an insulating material.

11. A method of manufacturing a display device, the method comprising:
preparing a circuit board including a plurality of protrusions;
seating the circuit board on a jig including a bottom portion and a plurality of electromagnets disposed on the bottom portion to be spaced apart from each other, and
determining whether the circuit board is seated in an exact position.

12. The method of claim 11, wherein the determining whether the circuit board is seated in the exact position includes:
detecting second alignment marks defined on each of the plurality of electromagnets and first alignment marks defined on each of the plurality of protrusions; and
determining a degree of tilt of the circuit board based on the first alignment marks and the second alignment marks.

13. The method of claim 12, wherein when it is detected that the first alignment marks and the second alignment marks are not located in a same straight line, it is determined that the circuit board is tilted and the circuit board is not seated in the exact position.

14. The method of claim 11, wherein the determining whether the circuit board is seated in the exact position includes: detecting a non-contact portion where the plurality of electromagnets and the plurality of protrusions are not in contact with each other.

15. The method of claim 14, further comprising:
supplying current to the plurality of electromagnets, before the detecting the non-contact portion.

16. The method of claim 14, further comprising:
detecting a number of the non-contact portion; and
calculating a compensation distance of the circuit board based on the number of the non-contact portion.

17. The method of claim 11, further comprising:
turning off power supplied to the plurality of electromagnets when it is determined that the circuit board is not seated in the exact position.

18. The method of claim 17, further comprising performing the seating the circuit board on the jig again after the turning off the power when it is determined that the circuit board is not seated in the exact position.

19. The method of claim 11,
further comprising: coupling the circuit board to a display panel of the display device when it is determined that the circuit board is seated in the exact position.

20. The method of claim 19, further comprising:
moving the jig on a rail to move the circuit board toward the display panel, before the coupling the circuit board to the display panel.
